(19) United States
(12) Patent Application Publication
(10) Pub. No.: US 2021/0074871 A1
(43) Pub. Date: Mar. 11, 2021

(54) INTERCONNECTIONS FOR PHOTOVOLTAIC ENERGY CELLS IN TANDEM MODULES

(71) Applicant: Miasole Hi-Tech Corp., Santa Clara, CA (US)

(72) Inventors: Timothy Nagle, San Jose, CA (US); Rouin Farshchi, Palo Alto, CA (US); Dmitry Poplavskyy, San Jose, CA (US)

(21) Appl. No.: 16/567,454

(22) Filed: Sep. 11, 2019

(51) Int. Cl. H01L 31/05; H01L 31/02; H01L 31/0224; H01L 31/18

(52) U.S. Cl. CPC H01L 31/05; H01L 31/02008; H01L 31/1884; H01L 31/022483; H01L 31/022475

(57) ABSTRACT

Described herein are interconnections for photovoltaic cells and/or photovoltaic modules. In some implementations, one or more first photovoltaic cells generate a first electric current in response to exposure to an illumination source. One or more second cells, which may be located in tandem with the one or more first photovoltaic cells, generate a second electric current in response to exposure to the illumination source. The one or more second cells may be coupled to an output terminal utilizing a conductive film comprising a plurality of conductive vias which function to conduct current from the one or more second cells to the output terminal. In particular embodiments, photovoltaic cells of first and second types may be independently tested and verified prior to being combined to form a tandemly-arranged photovoltaic module.

### BACKGROUND

Photovoltaic technology, which may be utilized in the construction of photovoltaic cells that convert electrical energy from an illumination source, such as the sun, into an electric current, is rapidly being adopted for household and business use as well as to provide power to the electrical grid. Photovoltaic systems may be implemented on structures, such as buildings, houses, and standalone platforms. Lightweight photovoltaic modules may also be utilized for installations on trucks, cars, boats, spacecraft, and other vehicles.

Photovoltaic modules are formed from individual photovoltaic cells, which can be arranged into photovoltaic modules, which, in turn, may be configured to form two-dimensional arrays of photovoltaic modules. Accordingly, as photovoltaic arrays may potentially utilize a large number of connections to accumulate electric currents from numerous photovoltaic cells at one or more centralized collection points, approaches toward arranging and interconnecting photovoltaic modules and cells in a manner that maximizes collection efficiency and minimizes resistive losses continues to be an active area of investigation.

### SUMMARY

Briefly, particular implementations may be directed to a photovoltaic module having one or more first cells to generate a first electric current in response to exposure to an illumination source. The module may additionally include one or more second cells, disposed over the one or more first cells, to generate a second electric current responsive to exposure to the illumination source. In certain implementations, the one or more second cells may be coupled to an output terminal utilizing a conductive film comprising one or more conductive vias, which may operate to transport current from the one or more second cells to the output terminal.

Particular implementations may be directed to a photovoltaic module having one or more first photovoltaic cells, which may operate to generate a first voltage based, at least in part, on a first bandgap voltage of a first active material. The photovoltaic module may additionally include one or more second photovoltaic cells, arranged in tandem with the one or more first photovoltaic cells, which may operate to generate a second voltage based, at least in part, on a second bandgap voltage of a second active material. The photovoltaic module may further include at least one conductive film disposed on either the first active material or on the second active material, in which the at least one conductive film includes one or more vias to transport an electric current from a first surface of the at least one conductive film to a second surface of the at least one conductive film.

Particular implementations may be directed to a method of constructing a four-terminal photovoltaic device, which may include forming one or more first photovoltaic cells, each comprising an active photovoltaic layer. The method may continue with forming one or more second photovoltaic cells, each comprising an active layer of a perovskite, in which the one or more second photovoltaic cells includes a conductor sandwiched between adhesive decals, wherein the conductor operates to couple an electric current from a first of the one or more second photovoltaic cells to a second of the one or more second photovoltaic cells. The method may further include joining the one or more first photovoltaic cells with a corresponding number of the one or more second photovoltaic cells to form a plurality of four-terminal photovoltaic cells.

In particular implementations may be directed to a four-terminal photovoltaic device including one or more first photovoltaic cells including an active photovoltaic layer. The device may additionally include one or more second photovoltaic cells, each comprising an active layer of a perovskite, in which the one or more second photovoltaic cells comprises a conductor sandwiched between adhesive decals, the conductor may be capable of coupling an electric current from a first of the one or more second photovoltaic cells to a second of the one or more second photovoltaic cells.

It should be understood that the aforementioned implementations are merely example implementations, and that claimed subject matter is not necessarily limited to any particular aspect of these example implementations.

### BRIEF DESCRIPTION OF THE DRAWINGS

FIG. 1A is a schematic diagram of a photovoltaic module having first and second active portions oriented in tandem with respect to each other, in accordance with certain embodiments.

FIG. 1B is a schematic diagram showing an equivalent circuit of the photovoltaic module of FIG. 1A, in accordance with certain embodiments.

FIG. 2A depicts an insulative film utilized in the construction of a photovoltaic module, in accordance with certain embodiments.

FIG. 2B depicts the insulative film of FIG. 2A, wherein localized material has been removed so as to form a via extending from the top surface of the insulative film to a bottom surface of the film, in accordance with certain embodiments.

FIG. 2C depicts a transparent conductive material formed on or over the insulative film, wherein the combination of the transparent conductive material and the insulative film have been brought into contact with an active photovoltaic material, in accordance with certain embodiments.

FIG. 2D depicts a top view of a transparent conductive material formed over the insulative film of FIG. 2C, wherein the combination of the transparent conductive material and the insulative film have been brought into contact with an active photovoltaic material, according to certain embodiments.

FIG. 3A depicts a photovoltaic cell of a first type disposed over an insulative decal and a conductor, in accordance with certain embodiments.

FIG. 3B depicts three of the photovoltaic cells of FIG. 3A arranged in a shingled manner to form a two-terminal photovoltaic module disposed over an insulative decal and a conductor, in accordance with certain embodiments.

FIG. 4A depicts a photovoltaic cell of a second type disposed over an insulative decal and a conductor, in accordance with certain embodiments.

FIG. 4B depicts the shingled arrangement of the photovoltaic cells of FIG. 3A disposed over a shingled arrangement of photovoltaic cells of a second type to form a four-terminal device, in accordance with certain embodiments.

FIG. 5 depicts a top view of the photovoltaic energy cell of FIG. 4B showing interconnecting wiring arranged in a serpentine pattern, in accordance with certain embodiments..

FIG. 6 depicts a first orientation of vias with respect to conductive wiring of a photovoltaic cell, according to certain embodiments.

FIG. 7 depicts conductive metal traces deposited on a transparent conductive material deposited over an insulative film, according to certain embodiments.

FIGS. 8A-8E depict sub-processes for forming a shingled arrangement of photovoltaic cells of a first type over photovoltaic cells of a second type, in accordance with certain embodiments.

FIGS. 9A-9F depict sub-processes for forming a shingled arrangement of photovoltaic cells of a first type over photovoltaic cells of a second type, in accordance with particular embodiments.

FIGS. 10A-10F depict sub-processes for forming a shingled arrangement of photovoltaic cells of a first type over photovoltaic cells of a second type, in accordance with alternative embodiments.

FIG. 11 depicts top views of photovoltaic layers having conductors arranged at approximately right angles to one another, in accordance with certain embodiments.

### DETAILED DESCRIPTION

In the following description, numerous specific details are set forth in order to provide a thorough understanding of the presented embodiments. The disclosed embodiments may be practiced without some or all of these specific details. In other instances, well-known process operations have not been described in detail so as to avoid unnecessarily obscuring the disclosed embodiments. While the disclosed embodiments are described in conjunction with the specific embodiments, it is to be understood that such description in association with particular embodiments is not intended to limit the disclosed embodiments.

Particular embodiments may provide arrangements of photovoltaic cells configured to form four-terminal devices. Accordingly, in certain embodiments, a photovoltaic module may include one or more first photovoltaic cells formed from a perovskite material, which responds to a first wavelength, or range of wavelengths, of radiant energy from an illumination source. Such response may include conversion of radiant energy from the illumination source into an electrical current. In particular embodiments, such as described herein, two or more photovoltaic cells may be arranged in a shingled manner, which permits a voltage generated by a first photovoltaic cell to be aggregated with a voltage generated by a second photovoltaic cell. By way of such an arrangement, “N” photovoltaic cells arranged serially and in a shingled manner may produce N times the voltage of a single photovoltaic cell.

In addition to shingling of two or more photovoltaic cells to produce an aggregated voltage with respect to a single photovoltaic cell, photovoltaic cells may be stacked on or over one another to form a tandem arrangement. In such a configuration, a first photovoltaic cell may comprise one or more transparent conductors, such as a transparent conductive oxide, which may permit radiant energy not absorbed by a first or upper layer to be conveyed to a second or lower layer. Accordingly, in certain embodiments, photovoltaic cells positioned at an upper layer of a module may absorb a first portion of an illumination spectrum, while photovoltaic cells positioned at a lower layer of the module may absorb a second portion of an illumination spectrum. In particular instances, it may be useful for a higher energy portion of an illumination spectrum to be absorbed by photovoltaic cells positioned at the upper layer and for a lower energy portion of an illumination spectrum to be absorbed by photovoltaic cells positioned at the lower layer, although claimed subject matter is not limited in this respect. Absorption by photovoltaic cells of a portion of an illumination spectrum may be determined by way of selection of photovoltaic materials having particular bandgap voltages corresponding to energy levels of a portion of an illumination spectrum.

In particular embodiments such stacking of shingled photovoltaic cells may permit a photovoltaic module, comprising one or more photovoltaic cells, to operate as a four-terminal device. In such four-terminal devices, a first pair of terminals may operate as a first current source, which may provide a current from one or more first active devices at a first voltage. A second pair of terminals of the four-terminal device may operate as a second current source, which may provide a current from one or more second active devices at a second voltage. In such devices, the first pair of terminals, coupled to the first current source, may operate independently from the second pair of terminals, coupled to the second current source. Four-terminal photovoltaic devices may advantageously overcome certain shortcomings of two-terminal photovoltaic devices. One such shortcoming may include instances in which one or more active devices generating less current in comparison to one or more other serially connected active devices may operate to limit overall current output of the two-terminal device.

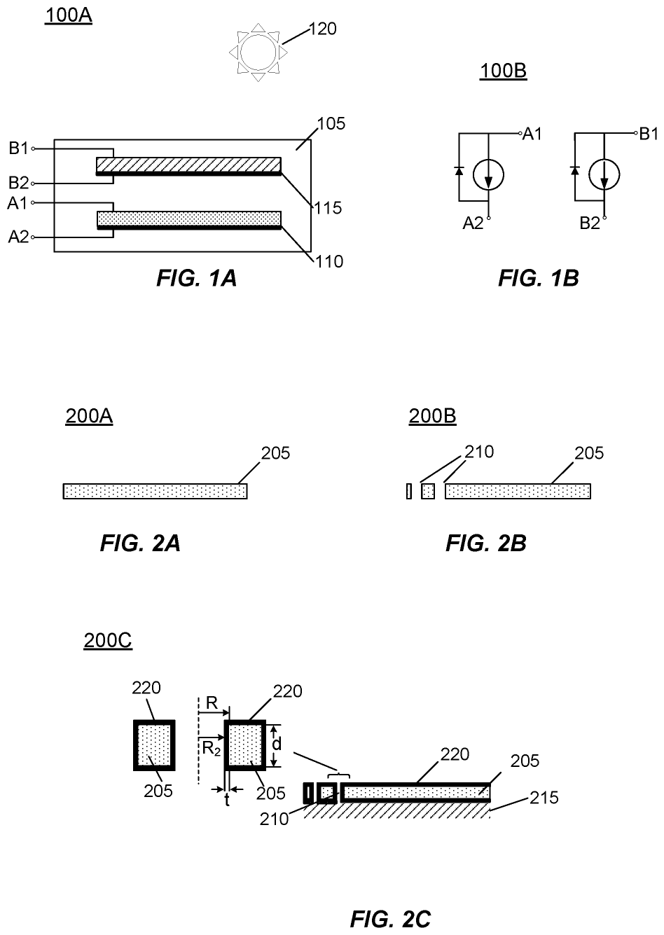

Turning now to the figures, FIG. 1A is a schematic diagram of a photovoltaic module having first and second active portions oriented in tandem with respect to each other, in accordance with certain embodiments. In the example embodiment 100A of FIG. 1A, photovoltaic module 105 comprises first photovoltaic cell 110, which comprises a first active material, and second photovoltaic cell 115, which comprises a second active material. In the embodiment of FIG. 1A, second photovoltaic cell 115 is situated at an “upper” layer, which implies that second photovoltaic cell 115 maintains a relatively unobstructed view of illumination source 120. In contrast, first photovoltaic cell 110 is situated at a “lower” layer, which implies that first photovoltaic cell 110 maintains an at least partially obstructed view of illumination source 120. However, in particular embodiments, second photovoltaic cell 115 is formed from relatively transparent materials, which permits passage of at least certain wavelengths of radiant energy from illumination source 120 to be received by first photovoltaic cell 110. In certain embodiments, first and second photovoltaic cells 110/115 may absorb complementary portions of the illumination spectrum radiated by illumination source 120, in which a first portion of the illumination spectrum is absorbed by first photovoltaic cell 110 while a second, nonoverlapping portion of the illumination spectrum is absorbed by second photovoltaic cell 115.

Accordingly, as shown in FIG. 1A, first and second photovoltaic cells 110/115 may each operate as an independent current source, having terminals A1-A2 and B1-B2. Thus, as shown in FIG. 1B (embodiment 100B), which is a schematic diagram showing an equivalent circuit of the photovoltaic module of FIG. 1A, in accordance with certain embodiments, exposure of photovoltaic module 105 to illumination source 120 may give rise to conduction of two independent currents. Such independent currents may comprise a first electric current conducted from reference terminal A2 to output terminal A1 and a second electric current conducted from reference terminal B2 to output terminal B1.

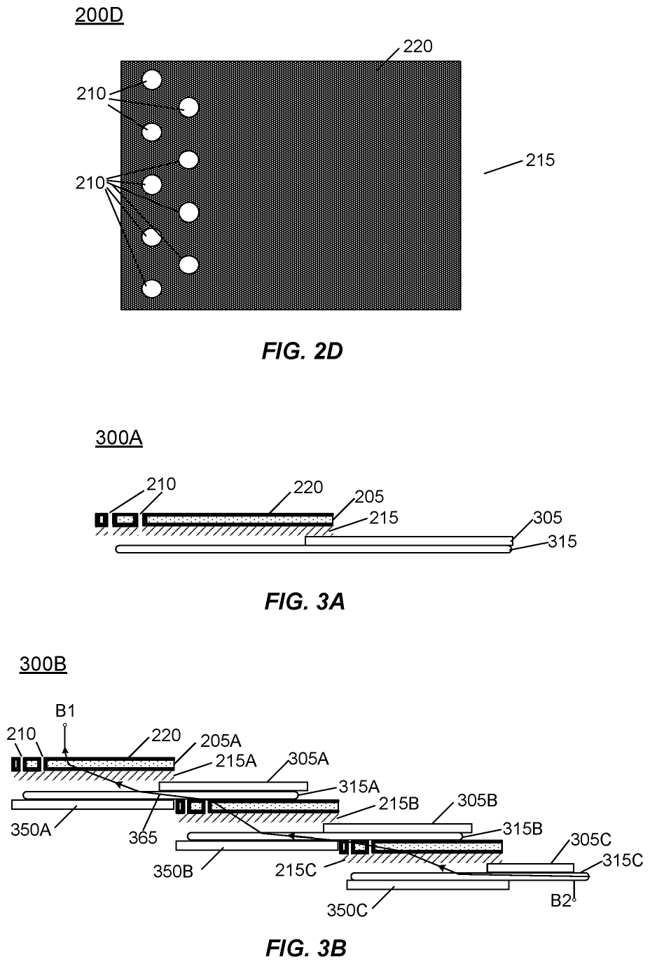

Turning now to the details of the construction of photovoltaic modules, FIG. 2A (embodiment 200A) depicts an insulative film utilized in the construction of a photovoltaic module, in accordance with certain embodiments. Insulative film 205 of FIG. 2A may comprise a transparent nonconductive plastic or glass resin having a thickness of between about 50.0 μm and about 250.0 μm. It should be noted, however, that claimed subject matter is intended to embrace transparent, nonconductive plastic or glass films having thicknesses less than 50.0 μm, such as 40.0 μm, 35.0 μm, 25.0 μm and so forth, or having thicknesses greater than 250.0 μm, such as 275.0 μm, 300.0 μm, and so forth. In particular embodiments, insulative film 205 may comprise at a material having at least 50.0% of a thermoplastic polymer resin, such as polyethylene terephthalate. In certain embodiments, insulative film 205 may comprise, poly(methyl methacrylate), fluorinated ethylene propylene, ethylene tetrafluoroethylene, polycarbonate, polyamide, polyetheretherketone, low density polyethylene, low-density urethane, or low-density polymer (with ionomer functionality), which may include poly(ethylene-co-methacrylic acid). It should be noted, however, that, claimed subject matter is intended to embrace any insulative film, virtually without limitation.

Insulative film 205 of FIG. 2A may undergo a process of removing a localized portion of material to create one or more vias, such as vias 210 of FIG. 2B (embodiment 200B), which extend from the top surface of the insulative film to a bottom surface of the film, in accordance with certain embodiments. Formation of via 210 may involve etching, laser scribing, drilling, milling, or may involve any other suitable technique that gives rise to formation of an elliptical, circular, oval, rectangular, triangular, or irregularly or other-shaped via, which extends between the top and bottom surfaces of insulative film 205.

FIG. 2C depicts a transparent conductive material formed on or over insulative film 205, wherein the combination of the transparent conductive material and insulative film 205 have been brought into contact with an active photovoltaic material, in accordance with certain embodiments. In FIG. 2C (embodiment 200C), insulative film 205 is coated with a transparent conductive material having a thickness of between about 50.0 nm and about 1000.0 nm or more. However, in particular implementations, insulative film 205 may comprise a transparent conductive material having a thickness of between about 200.0 nm and about 600.0 nm. Suitable transparent conductive materials may comprise a transparent conductive oxide (TCO) such as indium tin oxide, indium oxide, doped indium oxide, tin oxide, amorphous zinc-doped indium oxide, doped tin oxide, zinc oxide, aluminum zinc oxide, doped zinc oxide, ruthenium oxide, doped ruthenium oxide, or any combination thereof. A transparent conductive material may additionally include metallic nanowires, carbon nanotubes, or any combination thereof.

In FIG. 2C, details of via 210 are shown in detail to enhance the dimensions of features nearby via 210 and insulative film 205. For example, insulative film 205 may comprise a thickness d, which, as previously mentioned, may comprise a thickness of between 50.0 μm and 250.0 μm. Although not specifically identified in FIG. 2C, insulative film 205 may be coated with a transparent conductive material comprising a thickness (t) of between about between about 50.0 nm and about 1000.0 nm or more. However, in particular implementations, insulative film 205 may comprise a transparent conductive material having a thickness of between 200.0 nm and 600.0 nm. The transparent conductive material that coats insulative film 205 may extend throughout the inner (lateral) surfaces of via 210, so as to create a conductive path capable of transporting current from a first side (such as an upper side) to a second side (such as a lower side) of the coated film.

In embodiment 200C, assuming that via 210 comprises an approximately circular cross-section, as shown by the circular vias of FIG. 2D (embodiment 200D), a via coated with a transparent conductive material having a bulk resistivity “ρ,” a thickness “t,” and a via radius “R” through an insulating material of thickness “d.” Resistance of a conductive material coating inside surfaces of the via may be computed substantially in accordance with expression (1) below:

$$R = \frac{ρ d}{π t ( 2 R - t )} \qquad ( 1 )$$

Wherein t may be expressed as R-R₂, as shown in FIG. 2C. In one instance, ρ may include a resistivity of 10⁻³ Ω-cm, d=80.0 μm, R=50.0 μm, and t=500.0 nm. Under such circumstances, “R” of expression (1) may comprise a value of approximately 5.1 Ω. Accordingly, for an insulative film coated with a transparent conductive material and having N vias, resistivity may be approximated as 5.1/N Ω. For alternatively shaped vias not perfectly circular in shape, the resistance in expression (1) would remain proportional to the thickness of the insulating substrate and inversely proportional to the cross-sectional area of the conductive material within the via.

Thus, positioning of insulative film 205, coated by transparent conductive material 220, over active photovoltaic layer 215 may permit an electric current to conduct from layer 215 along the underside of insulative film 205 and through one or more of vias 210. In response to such current conduction, the electric current may be accessible at a top surface of insulative film 205. Additionally, in response to etching a plurality of vias, such as shown in FIG. 2D, the resistance contribution of the vias may be reduced to a negligible amount. Accordingly, large currents may be conducted from active photovoltaic layer 215, through vias 210, with reduced resistive losses.

Active photovoltaic layer 215 may correspond to a material comprising a molecular concentration of at least about 50.0% of perovskite. In this context, a perovskite material refers to a material having a chemical formula ABX₃; wherein A represents at least one of alkali metal ions, methylamine ions, ethylamine ions, NH₂CH═NH₂ ions or alkylamine ions, B represents at least one group IV element (e.g., carbon, silicon, germanium, tin, and lead), a group III (post-transition metals) of the periodic table of the elements (e.g., aluminum, gallium, indium, and thallium), or elements of group V of the periodic table of the elements (e.g. phosphorus, arsenic, antimony, and bismuth); and wherein X represents at least one element of group VII (halogens) of the periodic table of the elements (e.g., fluorine, chlorine, bromine, iodine, and astatine).

FIG. 2D depicts a top view of a transparent conductive material formed over the insulative film of FIG. 2C, wherein the combination of the transparent conductive material and the insulative film have been brought into contact with an active photovoltaic material, according to certain embodiments. In FIG. 2D (embodiment 200 D) a number (e.g., nine) of circular-shaped vias are etched or scribed into the transparent conductive material formed over the insulative film. Thus, utilizing expression 1, the total resistance of vias 210 can be estimated to be 5.1/9 Ω (0.567 Ω). It should be noted, however, that the selection of nine vias in FIG. 2D is merely an illustrative example, and claimed subject matter is intended to embrace any number of vias, such as one via, five vias, 10 vias, 25 vias, or hundreds of vias, virtually without limitation.

FIG. 3A depicts a photovoltaic cell of a first type disposed over insulative decal 305 and a conductive wire, in accordance with certain embodiments. In FIG. 3A (embodiment 300A), insulative decal 305 may include an adhesive surface which permits adherence of active photovoltaic layer 215 to underlying conductor 315. Insulative decal 305 may comprise a transparent plastic material having a thickness of between about 50.0 μm and 150.0 μm. Although FIG. 3A shows a separation between active photovoltaic layer 215 and conductor 315, dimensions of the components of FIG. 3A are not to scale. More particularly, in certain embodiments, insulative decal 305 may comprise a transparent material having thickness significantly less than that shown in FIG. 3A so as to permit an electrical connection between active photovoltaic layer 215 and conductor 315 in response to pressing photovoltaic layer 215 into contact with conductor 315. Accordingly, in the embodiment of FIG. 3A a current may be induced to flow from conductor 315, through active photovoltaic layer 215, and through vias 210, so as to be made available at an upward facing surface of insulative film 205 coated by transparent conductive material 220.

FIG. 3B (embodiment 300B) depicts three of the photovoltaic cells of FIG. 3A arranged in a shingled manner to provide a two-terminal photovoltaic module disposed over an insulative decal and a conductor, in accordance with certain embodiments. It should be noted that although three photovoltaic cells are arranged in a shingled manner, in other embodiments, any number of photovoltaic cells may be so arranged, such as fewer than three photovoltaic cells, or a number greater than three, such as four photovoltaic cells, five photovoltaic cells, 10 photovoltaic cells or any other number of cells, virtually without limitation. For the sake of clarity, only certain components of FIG. 3B are labeled. However, it should be noted that the three photovoltaic cells of FIG. 3B are identical to each other.

In certain embodiments, an additional adhesive decal, such as lower decals 350A, 350B, and 350C, may be situated beneath a portion of conductors 315A, 315B, and 315C (respectively). Lower decals 350A, 350B, and 350C may be utilized during fabrication of the photovoltaic module of FIG. 3B to provide and/or maintain contact of conductor 315A, 315B, and 315C with active photovoltaic layers 215A, 215B, and 215C. During fabrication of individual photovoltaic cells, lower decals may be trimmed or cut so as to control the extent of overlap between a lower decal and conductive wiring. It should additionally be noted that, as previously described, although active photovoltaic layers 215A, 215B, and 215C are shown as being separated from conductors 315A, 315B, and 315C, dimensions of the components of FIG. 3 are not to scale. Thus, in particular embodiments, transparent insulative decals 305A, 305B, and 305C may comprise a thickness significantly less than that shown in FIG. 3B, so as to permit electrical connection between active photovoltaic layers and underlying conductors.

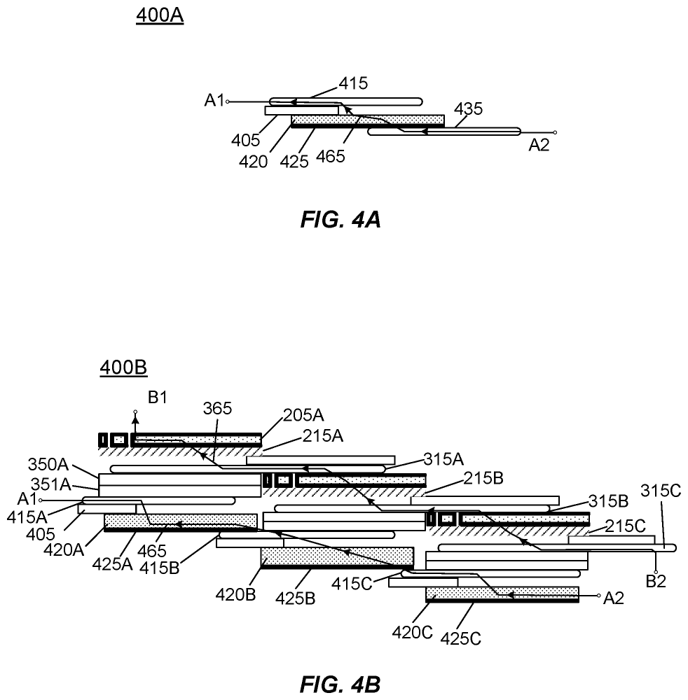

FIG. 4A depicts a photovoltaic cell of a second type disposed over an insulative decal and a conductor, in accordance with certain embodiments. In FIG. 4A (embodiment 400A), active photovoltaic layer 420 may correspond to a copper-indium-gallium-selenide (CIGS) cell, for example. In other embodiments, active photovoltaic layer 420 may correspond to a copper-indium-selenide/sulfide (CIS, CISSe) absorber, with an option of alloying or enhancing layer 420 with silver, a cadmium-telluride cell, an amorphous silicon cell, a micro-crystalline silicon cell, a crystalline silicon cell, a gallium arsenide multi-junction cell, a light absorbing dye cell, or an organic polymer cell. In particular embodiments, active photovoltaic layer 420 may be deposited on or over stainless-steel substrate 425, or other relatively flexible, strong, and electrically conductive substrate. Active photovoltaic layer 420 may be adhered to conductor 415 utilizing transparent insulative decal 405 that operates to maintain conductor 415 in contact with active photovoltaic layer 420. Accordingly, in response to being exposed to an illumination source, active photovoltaic layer 420 may induce an electric current or electrons to flow from reference terminal A2, through conductor 435 and in the direction of conductor 415. Thus, an electric current may be made available at output terminal A1. It should be noted that, in particular implementations, polarity of one or more devices may be reversed so as to bring about current flow in an opposite direction, such as from terminal A1 to terminal A2, and claimed subject matter is intended to embrace current flow in either direction. As described in relation to previously discussed figures herein, transparent insulative decal 405 may comprise a thickness that is significantly less than shown in FIG. 4A, so as to permit an electrical connection to be formed by pressing active photovoltaic layer 420 into contact with conductor 415.

FIG. 4B depicts a shingled arrangement of three of the photovoltaic cells of FIG. 4A disposed on or over the shingled arrangement of photovoltaic cells of FIG. 3B to form a four-terminal device, in accordance with certain embodiments. In FIG. 4B (embodiment 400B), photovoltaic cells of the first type include active photovoltaic layers that generate electric current responsive to absorption of radiant energy in a first range of wavelengths, while photovoltaic cells of the second type, located under or beneath the photovoltaic cells of the first type, generate electric current responsive to absorption of radiant energy in a second range of wavelengths. Accordingly, the arrangement of the first and second types of active photovoltaic layers absorb complementary portions of an illumination spectrum.

As shown in FIG. 4B, active photovoltaic layers 215A, 215B, and 215C function to induce electric current 365 to flow from reference terminal B2, through conductors 315A, 315B, and 315C, so that electric current 365 may be made available at output terminal B1 located at a conductive surface of coated insulative film 205A. As electric current 365 conducts through active photovoltaic layers 215A, 215B, and 215C, the voltage of the conducted current incrementally increases. In a similar manner, active photovoltaic layers 420A, 420B, and 420C, located under or beneath active photovoltaic layers 215A, 215B, and 215C function to induce electric current 465 to conduct from reference terminal A2, through conductors 415A, 415B, and 415C, so that the electric current may be made available at output terminal A1 located at conductor 415A. As electric current 465 conducts through active photovoltaic layers 425A, 425B, and 425C, the voltage of the conducted current incrementally increases.

It should be noted that during constructing of the shingled arrangement of the photovoltaic cells of FIG. 4B, additional insulative decal 351A, similar to insulative decal 350A, may be placed under or beneath lower decal 350A, 350B, and 350C. The addition of one or more decals under or beneath lower decals 350A, 350B, and 350C may provide increased structural integrity during fabrication of the shingled arrangement of photovoltaic cells.

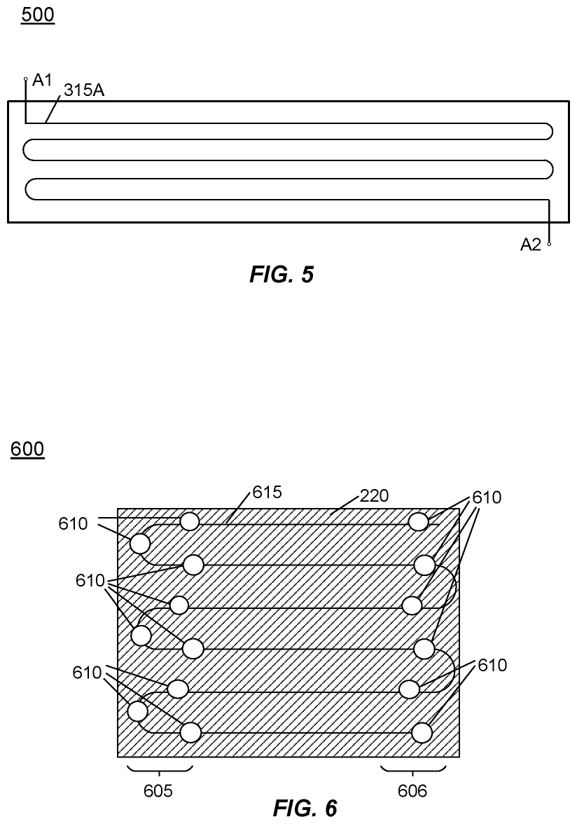

FIG. 5 (embodiment 500) depicts a top view of the photovoltaic energy cell of FIG. 4B showing interconnecting wearing arranged in a serpentine pattern, in accordance with certain embodiments. Although active photovoltaic layers as well as insulative decals and other features intervening between conductors are not depicted in FIG. 5, it may be appreciated that an electric current may be conducted from an end portion of conductor 315C (terminal A1) to an opposite end portion of conductor 315A (terminal A2). In certain embodiments, terminals A2 and A1 may be coupled to additional conductive wiring.

FIG. 6 depicts a first orientation of vias with respect to conductors of a photovoltaic cell, according to certain embodiments. In FIG. 6 (embodiment 600) vias 610 are shown in alignment with a conductor that traces a serpentine path, such as conductor 615. In particular embodiments, such alignment and/or co-location of vias with conductors may permit current coupled through a via to be conveyed directly from the via to the conductor. In particular embodiments, such direct coupling of a via and a conductor may minimize or preclude current conduction through thin regions of transparent conductive material 220. In FIG. 6, vias 610 may be positioned near a periphery, such as peripheral portions 605 and 606, of a two-dimensional array of photovoltaic modules. In particular embodiments, positioning of vias 610 near peripheral portions 605 and 606, may reduce the distance between vias 610 and output terminals, which, as depicted in FIG. 6, may also be positioned near peripheral portions of the array of photovoltaic modules. It should be noted that vias 610 may be alternatively positioned, such as randomly dispersed across the two-dimensional surface of an array of photovoltaic modules, and claimed subject matter is not limited in this respect.

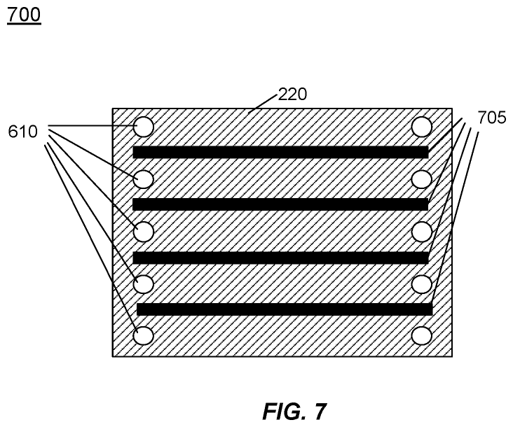

FIG. 7 depicts conductive metal traces deposited on a transparent conductive material deposited over an insulative film, according to certain embodiments. In FIG. 7 (embodiment 700), use of conductive traces 705 may operate to augment or enhance conductivity across a coated insulative film. Such conductive traces may provide a low-resistance current conduction across the surface of a photovoltaic module, so as to reduce resistive losses that may be incurred in response to potentially significant currents being coupled from vias 610 and traversing thin layers of transparent conductive material 220. In particular embodiments, such conductive traces may comprise a rectangular cross-section having a width of between about 10.0 μm and about 50.0 μm as well as a thickness of between about 500.0 nm and about 10.0 μm. In particular implementations, conductive traces may comprise a rectangular cross-section of between about 1.0 μm and about 5.0 μm.

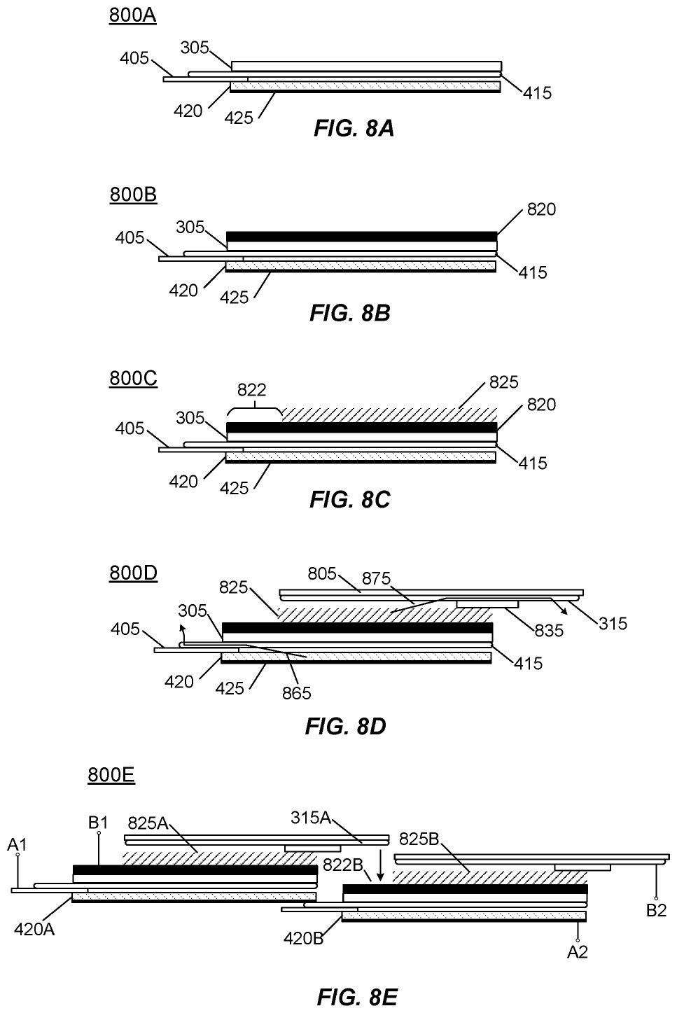

FIGS. 8A-8F depict sub-processes for forming a shingled arrangement of photovoltaic cells of a first type on or over photovoltaic cells of a second type (e.g., tandem), in accordance with certain embodiments. Forming such an arrangement may begin as depicted in FIG. 8A (embodiment 800A), in which active photovoltaic layer 420 is deposited over stainless-steel substrate 425 or deposited on or over any other relatively flexible, strong, and electrically conductive substrate. As previously mentioned herein, active photovoltaic layer 420 may correspond to a CIGS (copper-indium-gallium-selenide) cell, for example, or may correspond to copper-indium-selenide/sulfide (CIS, CISSe) absorber, as described in reference to FIG. 4A. Transparent insulative decal 405 may then be affixed or adhered to a portion of active photovoltaic layer 420. Decal 405 may operate to maintain conductor 415 in contact with active photovoltaic layer 420. Transparent insulative decal 305 may be arranged over conductor 415. The arrangement of components in FIG. 8A may then be pressed together so as to bring conductor 415 into contact with active photovoltaic layer 420. Accordingly, responsive to exposure of active layer 420 of FIG. 8A to an illumination source, a current may conduct between active layer 420 and conductor 415.

At FIG. 8B (embodiment 800B), transparent conductive material 820, which may comprise a transparent conductive oxide, may be deposited on insulative decal 305. In the embodiment of FIG. 8B, the deposited transparent conductive material may comprise a thickness of between about 50.0 nm and about 1000.0 nm. However, in particular implementations, a transparent conductive oxide deposited on insulative decal 305 may comprise a thickness of between about 200.0 nm and about 600.0 nm. At FIG. 8C (embodiment 800C), active photovoltaic layer 825, which may comprise a perovskite material having a thickness of between about 50.0 nm and about 1000.0 nm, may be deposited on transparent conductive material 820. In particular embodiments, a perovskite material may comprise a thickness of between about 200.0 nm and about 600.0 nm. In embodiment 800B, a portion of active photovoltaic layer 825 may be removed, such as by way of etching or laser scribing, so as to expose region 822 of transparent conductive material 820. Such exposure of a portion of transparent conductive material 820 may permit region 822 to make electrical contact with a portion of a conductive region of an adjacent photovoltaic cell (e.g., in a shingled arrangement), as will be discussed further in reference to FIG. 8D.

As depicted in FIG. 8D (embodiment 800D), insulative decal 835 may be adhered to a portion of active photovoltaic layer 825. In the embodiment of FIG. 8D, insulative decal 835 may operate to hold conductor 315 and insulative decal 805 in place over active photovoltaic layer 825. Thus, it may be appreciated that active photovoltaic layer 420 and active photovoltaic layer 825 form a tandem arrangement of photovoltaic cells. Hence, in response to exposure to an illumination source, current 865 may be induced to flow by way of active photovoltaic layer 420 and be made available at an output terminal located at conductor 415. Similarly, and also in response to exposure to an illumination source, current 875 may be induced to flow by way of active photovoltaic layer 825 and made available at an output terminal located on conductor 315. It should be noted that although shown as being physically separated in FIG. 8D, it is contemplated that in at least particular embodiments, conductors 315 and 415 may be pressed together or otherwise brought into contact with each other so as to bring about an electrical connection between active photovoltaic layer 420 and conductor 415 as well as between active photovoltaic layer 825 and conductor 315.

As depicted in FIG. 8E (embodiment 800E), tandemly arranged photovoltaic cells, in which a first photovoltaic cell comprises a perovskite-based active photovoltaic layer and in which a second photovoltaic cell comprises a CIGS cell, may be configured into a shingled arrangement. In such an arrangement, components of the first perovskite-based photovoltaic cell, such as conductor 315A may be pressed or sandwiched together with a conductive region of a second perovskite-based photovoltaic cell, such as conductive region 822B. Thus, responsive to exposure to an illumination source (e.g., sunlight), an electric current may be conducted from the active photovoltaic layer to a nearby conductor. In addition, depending upon a number of tandemly-arranged photovoltaic cells, the voltage of such current may be incrementally increased. Thus, for example, for the arrangement of FIG. 8E, a current conducted from terminal A1 may comprise a voltage that is about twice that of a voltage generated by each of active photovoltaic layers 420A and 420B. Further, a current conducted from terminal B2 of may comprise a voltage that is about twice that of a voltage generated by each of active photovoltaic layers of 825A and 825B. It should be noted that although only two tandemly-arranged photovoltaic pairs are depicted in FIG. 8E, embodiments of claimed subject matter are intended to embrace any number of tandemly-arranged photovoltaic pairs, such as 3, 4, 6, 10, etc., tandemly-arranged photovoltaic pairs, virtually without limitation.

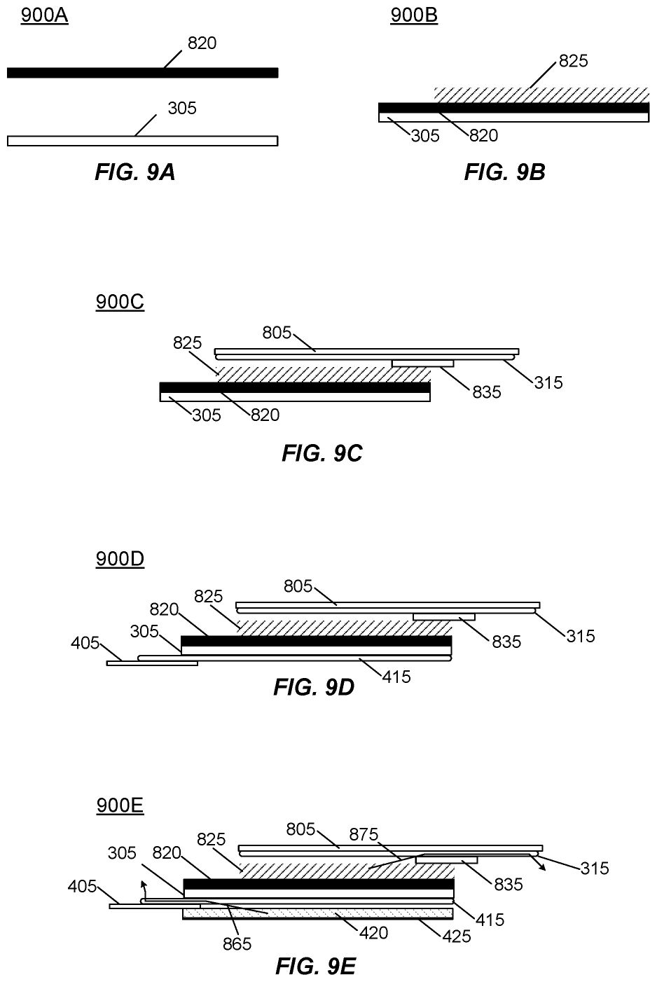

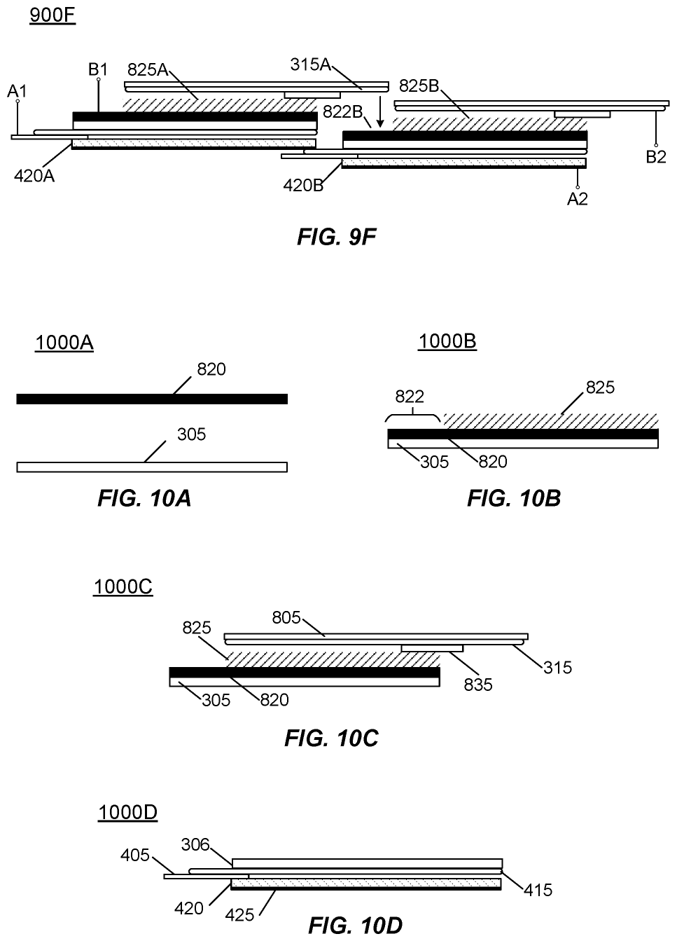

FIGS. 9A-9F depict sub-processes for forming a shingled arrangement of photovoltaic cells of a first type over photovoltaic cells of a second type, in accordance with particular embodiments. Forming such an arrangement may begin at FIG. 9A (embodiment 900A), in which transparent conductive material 820 may be deposited or otherwise formed over insulative decal 305. In particular embodiments, insulative decal 305 may comprise a transparent plastic material having a thickness of between about 50.0 μm and 150.0 μm. Transparent conductive material 820 may comprise a thickness of between about 50.0 nm and about 1000.0 nm. In particular implementations, transparent conductive material 820 may comprise a thickness of between about 200.0 nm and about 600.0 nm, although claimed subject matter is not limited in this respect.

As depicted in FIG. 9B (embodiment 900B), active photovoltaic layer 825 may be deposited on transparent conductive material 820. Active photovoltaic layer 825 may comprise a perovskite material having a thickness of between about 50.0 nm and about 1000 nm. In particular embodiments, a perovskite material may comprise a thickness of between about 200.0 nm and about 600.0 nm. In embodiment 900B, such patterning of the perovskite material may involve etching or laser scribing, so as to expose region 822 of transparent conductive material 820. Such exposure of a portion of transparent conductive material 820 may permit region 822 to make electrical contact with a portion of a conductive region of an adjacent photovoltaic cell (e.g., in a shingled arrangement), as will be discussed further in reference to FIG. 9F herein.

As depicted in FIG. 9C, (embodiment 900C), insulative decal 835 may be adhered to a portion of active photovoltaic layer 825. Insulative decal 835 may operate to hold conductor 315 and insulative decal 805 in place over active photovoltaic layer 825. In embodiments, insulative decal 835 may be sandwiched between conductor 315 and active photovoltaic layer 825. Accordingly, it may be appreciated that in response to exposure to an illumination source, active photovoltaic layer 825 may induce a current to conduct from layer 825, through conductor 315, so as to be made available at an output terminal of conductor 315.

As depicted in FIG. 9D (embodiment 900D), to permit formation of a second photoelectric cell under the perovskite-based photovoltaic cell of embodiment 900C (e.g., tandemly arranged), conductor 415 may be placed beneath insulative decal 305. Transparent insulative decal 405 may then be placed beneath conductor 415. Transparent insulative decal 405 may operate to maintain active photovoltaic layer 420 in contact with conductor 415. Thus, it may be appreciated that (as shown in FIG. 9E (embodiment 900E)) active photovoltaic layer 420 and active photovoltaic layer 825 form a tandem arrangement of photovoltaic cells. Hence, in response to exposure to an illumination source, current 865 may be induced to flow by way of active photovoltaic layer 420 and be made available at an output terminal located at conductor 415. Similarly, and also in response to exposure to an illumination source, current 875 may be induced to flow by way of active photovoltaic layer 825 and made available at an output terminal located on conductor 315. It should be noted that although shown as being physically separated in FIG. 9D, it is contemplated that in at least particular embodiments, conductor 315 and active photovoltaic layer 825 may be pressed together or otherwise brought into contact with each other so as to bring about an electrical connection between active photovoltaic layer 825 and conductor 315. Similarly, conductor 415 and active photovoltaic layer 420 may be pressed together or otherwise brought into contact with each other so as to bring about an electrical connection between active photovoltaic layer 420 and conductor 415.

As depicted in FIG. 9F (embodiment 900F), tandemly arranged photovoltaic cells, in which a first photovoltaic cell comprises a perovskite-based active photovoltaic layer and in which a second photovoltaic cell comprises a CIGS cell, may be configured into a shingled arrangement. In such an arrangement, components of the first perovskite-based photovoltaic cell, such as conductor 315A may be pressed or sandwiched together with a conductive region a second perovskite-based photovoltaic cell, such as conductive region 822B. Thus, responsive to exposure to an illumination source (e.g., sunlight), an electric current may be conducted from the active photovoltaic layer to a nearby conductor. In addition, depending upon a number of tandemly-arranged photovoltaic cells, the voltage of such current may be incrementally increased. Thus, for example, for the arrangement of FIG. 9F, a current conducted from terminal A1 may comprise a voltage that is about twice that of a voltage generated by each of active photovoltaic layers 420A and 420B. Similarly, a current conducted from terminal B2 of may comprise a voltage that is about twice that of a voltage generated by each of active photovoltaic layers 825A and 825B. It should be noted that although only two tandemly-arranged photovoltaic pairs are depicted in FIG. 9F, embodiments of claimed subject matter is intended to embrace any number of tandemly-arranged photovoltaic pairs, such as 3, 4, 6, 10, etc., tandemly-arranged photovoltaic pairs, virtually without limitation.

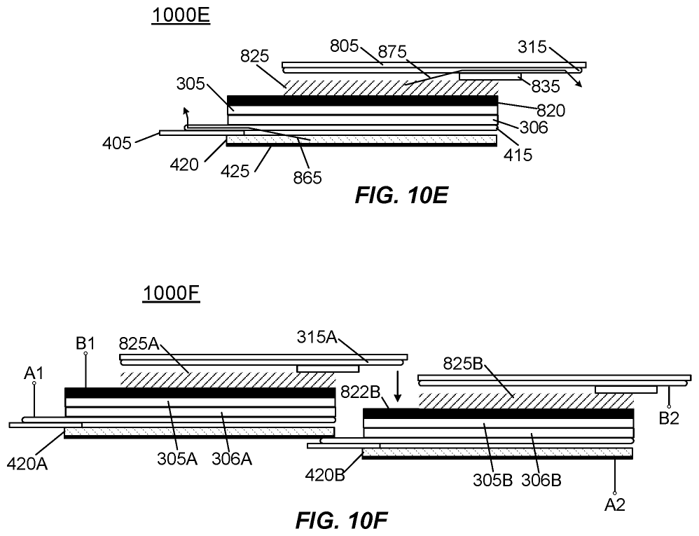

FIGS. 10A-10F depict sub-processes for forming a shingled arrangement of photovoltaic cells of a first type over photovoltaic cells of a second type, in accordance with alternative embodiments. Forming such an arrangement may begin as depicted in FIG. 10A (embodiment 1000A), in which active photovoltaic material 820 may be deposited or otherwise formed over insulative decal 305. In particular embodiments, insulative decal 305 may comprise a transparent plastic material having a thickness of between about 50.0 μm and 150.0 μm. Transparent conductive material 820 may comprise a thickness of between about 50.0 nm and about 1000.0 nm. In particular implementations, transparent conductive material 820 may comprise a thickness of between about 200.0 nm and about 600.0 nm, although claimed subject matter is not limited in this respect.

As depicted in FIG. 10B (embodiment 1000B), active photovoltaic layer 825 may be deposited on transparent conductive material 820. Active photovoltaic layer 825, which may comprise a perovskite material having a thickness of between about 50.0 nm and about 1000.0 nm. In particular embodiments, a perovskite material may comprise a thickness of between about 200.0 nm and about 600.0 nm. In embodiment 1000B, such patterning of the perovskite material may involve etching or laser scribing, so as to expose region 822 of transparent conductive material 820. Such exposure of a portion of transparent conductive material 820 may permit region 822 to make electrical contact with a portion of a conductive region of an adjacent photovoltaic cell (e.g., in a shingled arrangement), as will be discussed further in reference to FIG. 10F herein.

As depicted in FIG. 10C, (embodiment 1000C), insulative decal 835 may be adhered to a portion of active photovoltaic layer 825. Insulative decal 835 may operate to hold conductor 315 and insulative decal 805 in place over active photovoltaic layer 825. In embodiments, insulative decal 835 may be sandwiched between conductor 315 and active photovoltaic layer 825. Accordingly, it may be appreciated that in response to exposure to an illumination source, active photovoltaic layer 825 may induce a current to conduct from layer 825, through conductor 315, so as to be made available at an output terminal of conductor 315. As depicted in FIG. 10D (embodiment 1000D), to form a second photoelectric cell under the perovskite-based photovoltaic cell of embodiment 1000C (e.g., tandemly arranged), transparent insulative decal 405 may be affixed or adhered to a region of active photovoltaic layer 420. In the embodiment 1000 D, transparent insulative decal 405 may operate to maintain conductor 415 in electrical contact with photovoltaic layer 420. In particular embodiments, second insulative decal 306 may be placed on or over conductor 415.

Thus, it may be appreciated that active photovoltaic layer 420 and active photovoltaic layer 825 can be utilized to form a tandem arrangement of photovoltaic cells as shown in FIG. 10E. It may also be appreciated that the photovoltaic cells of embodiment 1000C and 1000D may represent embodiments in which two separate photovoltaic cells may be independently fabricated and tested. Thus, prior to integration of perovskite-based photovoltaic cells and CIGS-based photovoltaic cells, nonfunctioning or marginally-functioning photovoltaic cells, such as photovoltaic cells that do not provide at least nominal current-generating parameters, may be discarded. Accordingly, a tandem arrangement of photovoltaic cells, in which a first photovoltaic cell utilizes a perovskite-based active layer, and in which a second photovoltaic cell utilizes a CIGS-based active layer, may be integrated so as to form a tandem arrangement only after operation of both types of photovoltaic cells has been verified. In particular embodiments, such verification in the operation of a perovskite-based photovoltaic cell as well as verification in the operation of a CIGS-based photovoltaic cell may ensure that a tandemly-arranged photovoltaic cell, comprising both types of photovoltaic cells, can be expected to operate satisfactorily.

Thus, following fabrication and verification of a perovskite-based photovoltaic cell and fabrication and verification of a CIGS-based photovoltaic cell, as shown in FIG. 10E, current 865 may be induced to flow by way of active photovoltaic layer 420 and be made available at an output terminal located at conductor 415. Similarly, current 875 may be induced to flow by way of active photovoltaic layer 825 and made available at an output terminal located on conductor 315. It should be noted that although shown as being physically separated in FIG. 10E, it is contemplated that in at least particular embodiments, conductors 315 and 415 may be pressed together or otherwise brought into contact with each other so as to bring about an electrical connection between active photovoltaic layer 420 and conductor 415 as well as between active photovoltaic layer 825 and conductor 315.

As depicted in FIG. 10F (embodiment 1000F), tandemly arranged photovoltaic cells, in which a first photovoltaic cell comprises a perovskite-based active photovoltaic layer and in which a second photovoltaic cell comprises a CIGS cell, may be configured into a shingled arrangement. In such an arrangement, components of the first perovskite-based photovoltaic cell, such as conductor 315A may be pressed or sandwiched together with a conductive region of a second perovskite-based photovoltaic cell, such as conductive region 822B. Thus, responsive to exposure to an illumination source (e.g., sunlight), an electric current may be conducted from the active photovoltaic layer to a nearby conductor. In addition, depending upon a number of tandemly-arranged photovoltaic cells, the voltage of such current may be incrementally increased. Thus, for example, for the arrangement of FIG. 10F, a current conducted from terminal A1 may comprise a voltage that is about twice that of a voltage generated by each of active photovoltaic layers 420A and 420B. Similarly, a current conducted from terminal B2 may comprise a voltage that is about twice that of a voltage generated by each of active photovoltaic layers 825A and 825B. It should be noted that although only two tandemly-arranged photovoltaic pairs are depicted in FIG. 10F, embodiments of claimed subject matter are intended to embrace any number of tandemly-arranged photovoltaic pairs, such as 3, 4, 6, 10, etc., tandemly-arranged photovoltaic pairs, virtually without limitation. Insulative decals 305A and 306A serve to provide increased electrical insulation between a first pair of tandemly-arranged photovoltaic cells, while insulative decals 305B and 306B serve to provide increased electrical insulation between a second pair of tandemly-arranged photovoltaic cells.

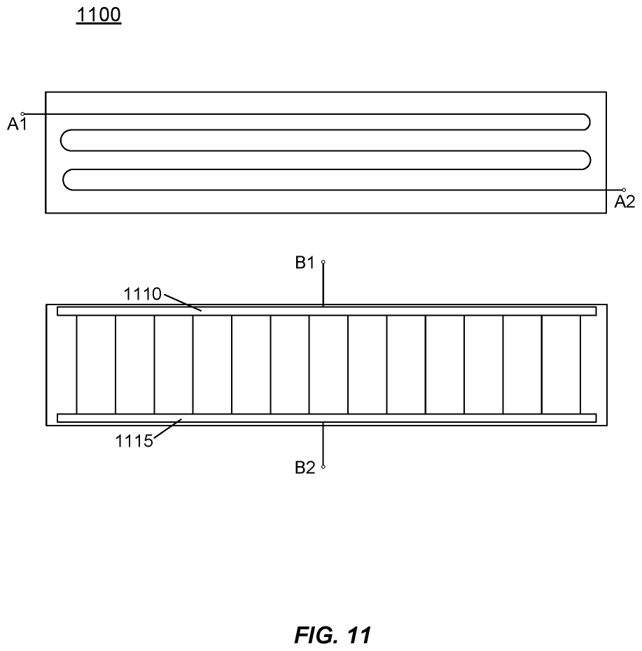

FIG. 11 (embodiment 1100) depicts top views of photovoltaic layers having conductors arranged at approximately right angles to one another, in accordance with certain embodiments. In such an arrangement, a conductor for conducting current between terminals A1 and A2, such as current generated or induced by a CIGS-based active photovoltaic layer, may trace a serpentine path. In contrast, conductors (e.g., 1110 and 1115) for conducting current between terminals B1 and B2, which may correspond to current generated or induced by a perovskite-based active photovoltaic layer, may trace a pattern that is substantially perpendicular to the serpentine pattern. In particular embodiments, such an arrangement of current-carrying conductors may bring about an ability to couple external conductors to output terminals in a manner that more evenly distributes such couplings. For example, output and reference voltage couplings to conduct current from CIGS-based active photovoltaic layers may be formed at first opposite sides of a shingled arrangement of photovoltaic cells, while output and reference voltage couplings to conduct current from perovskite-based active photovoltaic layers may be formed at second opposite sides of the shingled arrangement of photovoltaic cells. Such an arrangement may avoid crowding of power couplings by permitting such couplings to be spread more evenly among the four cardinal edges (e.g., separated by)90.0° of a rectangular photovoltaic array.

Although the foregoing invention has been described in some detail for purposes of clarity of understanding, it will be apparent that certain changes and modifications may be practiced within the scope of the appended claims. It should be noted that there are many alternative ways of implementing the processes, systems and apparatus of the present invention. Accordingly, the present embodiments are to be considered as illustrative and not restrictive, and the invention is not to be limited to the details given herein.

1. A photovoltaic module, comprising:
one or more first cells to generate a first electric current in response to exposure to an illumination source; and
one or more second cells, disposed over the one or more first cells, to generate a second electric current in response to exposure to the illumination source, the one or more second cells being coupled to an output terminal utilizing a conductive film comprising a plurality of conductive vias to transport current from the one or more second cells to the output terminal.

2. The photovoltaic module of claim 1, wherein the one or more second cells comprise one or more layers of transparent material to permit illumination from the illumination source to be conveyed through the one or more second cells to the one or more first cells.

3. The photovoltaic module of claim 1, wherein the one or more vias are positioned to be in alignment with one or more conductors that conduct an electric current between at least a first one of the one or more second cells and at least a second one of the one or more second cells.

4. The photovoltaic module of claim 1, wherein the one or more vias operate to bring about current conduction from a first side of a coated insulative film to a second side of the coated insulative film.

5. The photovoltaic module of claim 4, wherein the one or more vias comprise one or more layers of conductive material at a lateral surface of the via.

6-7. (canceled)

8. The photovoltaic module of claim 1, wherein at least one of the one or more first cells or at least one of the one or more second cells comprise a molecular concentration of at least 50.0% of a perovskite material, the perovskite material having a chemical formula of ABX₃, wherein “A” denotes at least one of an alkali metal ion, a methylamine ion, an ethylamine ion NH₂CH═NH₂ ions or alkylamine ions, B represents at least one group IV element (e.g., carbon, silicon, germanium, tin, and lead), group III (post-transition metals) of the periodic table of the elements (e.g., aluminum, gallium, indium, and thallium), or elements of group V of the periodic table of the elements (e.g. phosphorus, arsenic, antimony, and bismuth); and wherein X represents at least one element of group VII (halogens) of the periodic table of the elements (e.g., fluorine, chlorine, bromine, iodine, and astatine).

9-12. (canceled)

13. A photovoltaic module, comprising:
one or more first photovoltaic cells to generate a first voltage based, at least in part, on a first bandgap voltage of a first active material;
one or more second photovoltaic cells, arranged in tandem with the one or more first photovoltaic cells, to generate a second voltage based, at least in part, on a second bandgap voltage of a second active material; and
at least one conductive film disposed on either the first active material or on the second active material, the at least one conductive film comprising one or more vias to transport an electric current from a first surface of the at least one conductive film to a second surface of the at least one conductive film.

14. The photovoltaic module of claim 13, wherein the at least one conductive film comprises a conductive coating having a molecular concentration of at least 50.0% of a transparent conductive material.

15. The photovoltaic module of claim 14, wherein the transparent conductive material comprises indium oxide, indium tin oxide, doped indium oxide, tin oxide, doped tin oxide, zinc oxide, aluminum zinc oxide, doped zinc oxide, ruthenium oxide, doped ruthenium oxide, or any combination thereof.

16. The photovoltaic module of claim 13, wherein the at least one conductive film is disposed on the first active material, and wherein the first active material comprises a perovskite having a molecular concentration of at least 50.0% of ABX₃, wherein “A” denotes at least one of an alkali metal ion, a methylamine ion, an ethylamine ion, NH₂CH═NH₂ ions or alkylamine ions, B represents at least one group IV element (e.g., carbon, silicon, germanium, tin, and lead), a group III (post-transition metals) of the periodic table of the elements (e.g., aluminum, gallium, indium, and thallium), or elements of group V of the periodic table of the elements (e.g. phosphorus, arsenic, antimony, and bismuth); and wherein X represents at least one element of group VII (halogens) of the periodic table of the elements (e.g., fluorine, chlorine, bromine, iodine, and astatine).

17. The photovoltaic module of claim 13, wherein the one or more vias to transport the electric current from the first surface to the second surface are arranged to align with a peripheral portion of the first surface of the at least one conductive film.

18. The photovoltaic module of claim 13,
wherein the one or more first photovoltaic cells comprise at least two first photovoltaic cells arranged in a shingled relationship, or
wherein the one or more second photovoltaic cells comprise at least two second photovoltaic cells arranged in a shingled relationship.

19. The photovoltaic module of claim 13, wherein the one or more first photovoltaic cells and the one or more second photovoltaic cells operate to absorb complementary portions of an illumination spectrum.

20-28. (canceled)

29. A four-terminal photovoltaic device, comprising:
one or more first photovoltaic cells comprising an active photovoltaic layer; and
one or more second photovoltaic cells comprising an active layer of a perovskite, the one or more second photovoltaic cells comprising a conductor sandwiched between adhesive decals, the conductor capable of coupling an electric current from a first of the one or more second photovoltaic cells to a second of the one or more second photovoltaic cells.

30. The device of claim 29, wherein a first cell of the one or more second photovoltaic cells is electrically connected to a second cell of the one or more second photovoltaic cells via connecting the conductor sandwiched between the adhesive decals of the first cell with a transparent conductive material coated substrate of the second cell to form a shingled relationship between the first cell and the second cell.

31. The device of claim 30, wherein the transparent conductive material comprises indium oxide, indium tin oxide, doped indium oxide, tin oxide, doped tin oxide, zinc oxide, aluminum zinc oxide, doped zinc oxide, ruthenium oxide, doped ruthenium oxide, or any combination thereof.

32. The device of claim 29, wherein the four-terminal photovoltaic device comprises a rectangular shape, and wherein at least one terminal of the four-terminal photovoltaic device is disposed at a first edge of the rectangle, and wherein at least a second terminal of the four terminal photovoltaic device is disposed at a second edge of the rectangle, the first edge of the rectangle and the second edge of the rectangle being angularly separated by at least about 90.0°.

33. The device of claim 29, wherein the perovskite comprises a molecular concentration of at least 50.0% of ABX₃, wherein “A” denotes at least one of an alkali metal ion, a methalamine ion, an ethylamine ion, NH₂CH═NH₂ ions or alkylamine ions, B represents at least one group IV element (e.g., carbon, silicon, germanium, tin, and lead), a group III (post-transition metals) of the periodic table of the elements (e.g., aluminum, gallium, indium, and thallium), or elements of group V of the periodic table of the elements (e.g. phosphorus, arsenic, antimony, and bismuth); and wherein X represents at least one element of group VII (halogens) of the periodic table of the elements (e.g., fluorine, chlorine, bromine, iodine, and astatine).

34. The device of claim 29, wherein the active layer of the first photovoltaic cells comprises CIGS and additionally comprises silver.

35. The device of claim 29, wherein the adhesive decal comprises at least about 50.0% of Polyethylene terephthalate.
